(19) United States
(12) Patent Application Publication
(10) Pub. No.: US 2013/0154994 A1
(43) Pub. Date: Jun. 20, 2013

(54) TRANSPARENT CAPACITIVE TOUCH PANEL WITH ELECTROMAGNETIC SHIELDING EFFECT

(71) Applicant: Kai-Ti YANG, Taoyuan (TW)

(72) Inventor: Kai-Ti YANG, Taoyuan (TW)

(21) Appl. No.: 13/326,349

(22) Filed: Dec. 15, 2011

(51) Int. Cl. G06F 3/044; H05K 9/00

(52) U.S. Cl. 345/174; 361/818

(57) ABSTRACT

A transparent capacitive touch panel has electromagnetic shielding effect. No extra process and cost is increased. A side of the capacitive touch panel facing electromagnetic interference is formed with an electromagnetic (EM) shielding for avoiding the interference of EMI and RFI. As comparing with the prior art, advantages of the present invention are that the present invention achieves a complete EM-proof effect so as to provide a preferred EM shielding; the effect of EM proof of the present invention has no relation with the arrangement of X traces, Y traces; and the gaps between the traces of the present invention can be widened for having a better effect of EM proof so as to simplify the technology in manufacturing with a higher yield ratio and a lower cost.

### FIELD OF THE INVENTION

The present invention relates to touch panels, and in particular to a transparent capacitive touch panel with electromagnetic shielding effect.

### BACKGROUND OF THE INVENTION

Transparency touch panel is used to cover the display screen of an electronic device for interactive inputting so as to improve the interaction between the user and the device in an efficiency way. A touch panel is made of sensors, a control panel and other software. Based on the operation principle and the structure, the touch panels are classified as resistive, capacitive, infrared and supersonic touch panels, etc. However currently, capacitive touch panels with multiple sensing points are the main trend in the improvement of the touching sensing effect, cracking-proof and wearing-proof because it uses the function of single point sensing. Generally, a capacitive touch panel has two transparent conductive films which are insulated from one another, such as made of ITO. Each film has a desire electrode pattern to form as a plurality of X traces and Y traces. The undesired portions on the film are etched out to form with the traces and these traces are isolated with a predetermined width. However, in use of the capacitive touch panel, the external EMI (electromagnetic interference) or RFI (radio frequency interference) will cause the touch panel to generate error signals, even the whole touch panel can not work. Therefore, it is necessary to remove the effects of EMI and RFI.

In one current design for avoiding EMI and RFI is to install a substrate to a capacitive touch panel. The X or Y traces at one lateral side of the substrate is widened fully so that the gap between different traces is only 30 micrometers to form as an EM shielding layer. However, the small gap therebetween will cause the difficulty in manufacture, the reduction of yield ratio and the cost to be doubled.

### SUMMARY OF THE INVENTION

The present invention serves to provide a transparent capacitive touch panel with electromagnetic shielding effect, wherein no extra process and cost is increased. A side of the capacitive touch panel facing electromagnetic interference is formed with an electromagnetic (EM) shielding for avoiding the interference of EMI and RFI. As comparing with the prior art, advantages of the present invention are that the present invention achieves a complete EM-proof effect so as to provide a preferred EM shielding; the effect of EM proof of the present invention has no relation with the arrangement of X traces, Y traces; and the gaps between the traces of the present invention can be widened for having a better effect of EM proof so as to simplify the technology in manufacturing with a higher yield ratio and a lower cost.

### BRIEF DESCRIPTION OF THE DRAWINGS

FIG. 1 is a schematic view about the exploded view of the first embodiment of the present invention.

FIG. 2 is a lateral cross sectional view of the first embodiment of the present invention.

FIG. 3 is a lateral cross sectional view of the second embodiment of the present invention.

FIG. 4 is a lateral cross sectional view of the third embodiment of the present invention.

FIG. 5 is a lateral cross sectional view of the fourth embodiment of the present invention.

FIG. 6 is a lateral cross sectional view about the fifth embodiment of the present invention.

FIG. 7 is a lateral cross sectional view about the sixth embodiment of the present invention.

FIG. 8 is a lateral cross sectional view about the seventh embodiment of the present invention.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

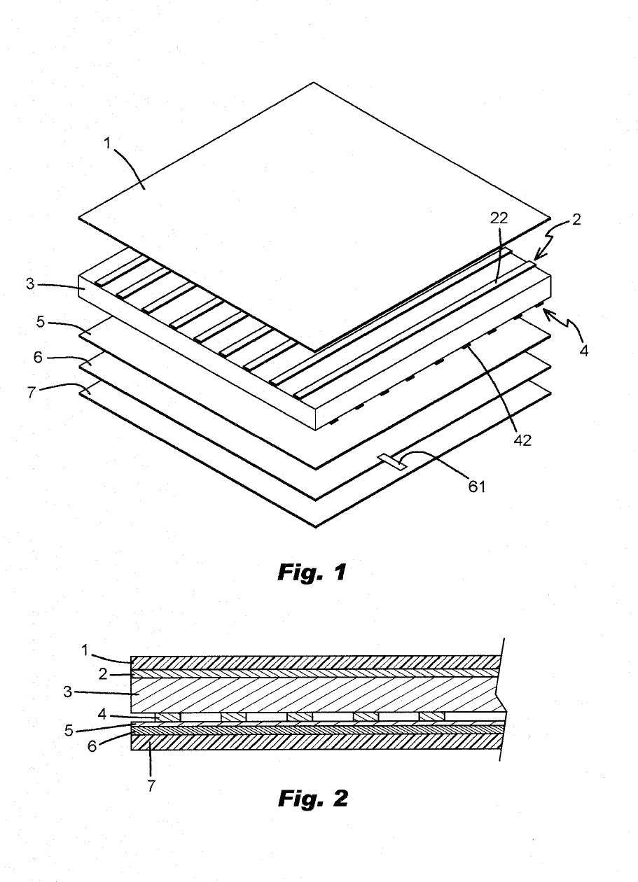

With reference to FIGS. 1 and 2, the first embodiment of the present invention is illustrated. The structure of the present invention includes the following elements, an upper protecting layer 1, an X trace layer 2, a substrate 3, a Y trace layer 4, an insulation layer 5, a conductive optical clear adhesive (OCA) layer 6 and a lower protection layer 7 which are arranged sequentially so as to be overlapped as a capacitive touch panel. In this embodiment, the upper protection layer 1 is a surface layer or an upper cover of the capacitive touch panel. Generally, the upper protection layer 1 and the lower protection layer 7 are high transparency insulating thin layers, such as glass, PET (Polythylene terephthalate , PET), PC (Polycarbonate, PC), etc. However, these are not used to confine the scope of the present invention. The substrate 3 is a hard transparent thin plate with a material selected from glass, PET, PC, PMMA (polymethylmethacrylate PMMA) or COC (Cyclic Olefin Copolymer), etc., but these are not used to confine the scope of the present invention. The insulation layer 5 is a high transparency insulating thin layers, such as polyester, insulation ink, UV curable adhesive, or OCA, etc., but these arc not used to confine the scope of the present invention. The conductive OCAlayer 6 is a high transparency conductive OCA with a material selected from PEDOT/PSS copolymer [Poly (3,4-ethylenedioxythiophene)—poly (styrenesulfonate)], but this is not used to confine the scope of the present invention, for example, conductive OCA with Antistatic Agent materials having Ionic Surfactant or Nonionic Surfactant. The conductive OCA layer 6 is a thin layer or a solution which can be coated or printed to the touch panel, especially, the conductive OCA layer 6 has a surface resistivity within an interval of 10 to 10000 Ω·cm-2 with a thickness between 0.01 to 300 μm. The X trace layer 2 and Y trace layer 4 are made of material of (ITO) transparency conductive thin film. The X trace layer 2 includes a plurality of parallel X traces 22 and the Y trace layer 4 includes a plurality of parallel Y traces 42. Above layers are sequentially arranged, the X trace layer 2 is formed at a lower side of the upper protection layer 1. The Y trace layer 4 is spaced with the X trace layer 2 through the substrate 3. The X traces 22 are orthogonally arranged with the Y traces 42. The conductive OCA layer 6 flatly glues the insulation layer 5 to the lower protection layer 7. A lateral edge of the conductive OCA layer 6 is grounded through a conductor 61 thereof. The conductor 61 is selected from a copper foil or a FPT (flexible printed circuit).

In above structure, the X trace layer 2 and Y trace layer 4 are formed as a capacitive touch sensing loop, When a finger touches through the upper protection layer 1, a capacitive signal is triggered and thus the touching position can be known. In this embodiment, the conductive OCA layer 6 serves to avoid the interferences from EMI and RFI so as not to affect the operation of the capacitive touching sensing loop and thus no error signals are generated.

Referring to FIG. 3, the second embodiment of the present invention is illustrated. In the second embodiment, the structure of the present invention includes an upper protection layer 1, a X trace layer 2, a substrate 3, a Y trace layer 4, a lower protection layer 7 and a conductive thin film 8. The structures of the upper protection layer 1, X trace layer 2, substrate 3, Y trace layer 4 and the lower protection layer 7 are identical to those shown in the first embodiment. Thus the details of these layers will not be further described herein. The conductive thin film 8 is a thin film with high transparency having a surface resistivity between 10 to 10000 Ω·cm⁻² . A lateral side of the conductive thin film 8 is grounded through a conductor. The conductive thin film 8 may be a metal netlike thin film or a nano-silver evaporated film, such as that manufactured by Cima NanoTech. Besides, other transparent thin films with good conductivity are also suitable, such as thin films of Indium Tin Oxide (ITO), Indium Zinc Oxide (IZO), Aluminum Zinc Oxide (AZO) or PEDOT, but these are not used to confine the scope of the present invention. Furthermore, the conductive material 8 (for example, PEDOT:PSS or antistatic agent material) can be directly installed on the lateral sides of the lower protection layer 7 through a hard coating process. The conductive thin film 8 has the effect of isolating the affect from EMI and RFI so as to assure the affective operation of the capacitive touch panel.

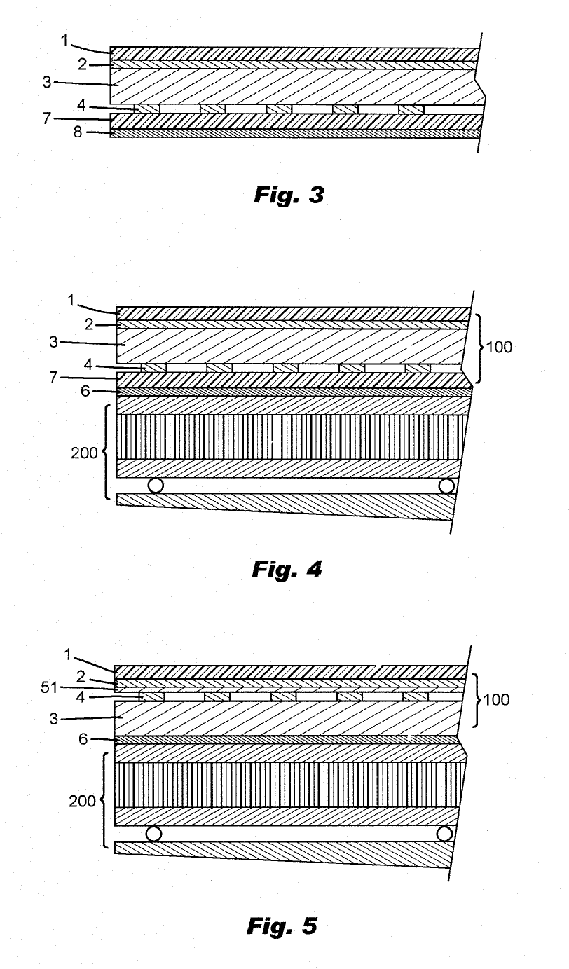

With reference to FIG. 4, the third embodiment of the present invention is illustrated. In this embodiment, a touch panel is arranged on an LCM (Liquid Crystal Display Module). The touch panel 100 in this embodiment includes an upper protection layer 1, a X trace layer 2, a substrate 3, a Y trace layer 4 and a lower protection layer 7. These layers are sequentially arranged. Then a conductive OCA layer 6 serves to glue the touch panel 100 to the LCM 200. A lateral side of the conductive OCA layer 6 is grounded through a conductor (not shown). The layers 1, 2, 3, 4, 6 and 7 are identical to the layers described the first embodiment and thus the details thereof will not be further described herein. In this embodiment, the conductive OCA layer 6 has the effect of avoiding the interference of EMI and RFI so as not to affect the operation of the touch panel and thus no error signal occurs. The manufacturing process is not complicated and the cost is retained. Furthermore, the EM shielding of the touch panel is enhanced.

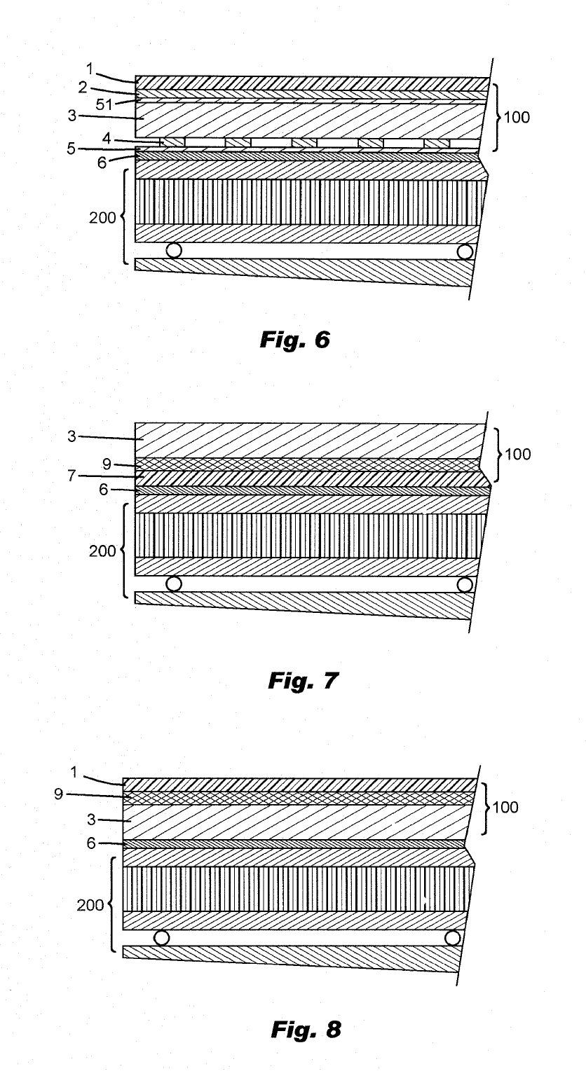

With reference to FIGS. 5 and 6, it is illustrated that two touch panels 100 of different structures are arranged on the LCM 200. In FIG. 5, the touch panel 100 is formed by an upper protection layer 1, an X trace layer 2, an insulating gluing layer 51, a Y trace layer 4, and a substrate 3. All above mentioned layers are sequentially arranged as a capacitance touch panel. The touch panel in FIG. 6 is formed by an upper protection layer 1, an X trace layer 2, an insulating gluing layer 51, a substrate 3, a Y trace layer 4, and a insulating layer 4 which are sequentially arranged. The touch panel 100 in FIG. 7 includes a substrate 3, an sensing electrode layer 9 and a lower protection layer 7. The touch panel in FIG. 8 is formed by an upper protection layer 1, a sensing electrode layer 9 and a substrate 3. Especially, the sensing electrode layer 9 installs the X traces and Y traces on the same layer. All the layers of the touch panel 100 are sequentially arranged as a capacitive touch panel. Then a conductive OCA layer 6 serves to adhere a bottom surface of the touch panel 100 to the LCM 200. One lateral edge of the conductive OCA layer 6 is grounded through a conductor (not shown). Like above mentioned third embodiment, the conductive OCA layer 6 has the effect of preventing EMI and RFI.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A transparent capacitive touch panel with electromagnetic shielding effect, comprising: a capacitive touch sensing unit, a plurality of isolating layers, and at least one conductive thin film; the capacitive touch sensing unit being installed between two isolating layers;
wherein the conductive thin film is installed at a side of the capacitive touch sensing unit facing an electromagnetic interference source, and is grounded and has an effect of shielding all the capacitive touch sensing unit from interference of electromagnetic interference; a surface resistivity of the conductive thin film is between 10 and 10,000 Ω·cm⁻².

2. The transparent capacitive touch panel with electromagnetic shielding effect as claimed in claim 1, wherein the conductive thin film is a conductive optical clear adhesive.

3. The transparent capacitive touch panel with electromagnetic shielding effect as claimed in claim 2, wherein the conductive optical clear adhesive is a PEDOT/PSS copolymer [Poly (3,4-ethylenedioxythiophene)—poly(styrenesulfonate)].

4. The transparent capacitive touch panel with electromagnetic shielding effect as claimed in claim 2, wherein the conductive optical clear adhesive contains antistatic agent material.

5. The transparent capacitive touch panel with electromagnetic shielding effect as claimed in claim 3, wherein the antistatic agent material is ion-interface agent or non-ion interface agent.

6. The transparent capacitive touch panel with electromagnetic shielding effect as claimed in claim 1, wherein the conductive thin film is a metal netlike thin film.

7. The transparent capacitive touch panel with electromagnetic shielding effect as claimed in claim 1, wherein the conductive thin film is nano- silver evaporating film.

8. The transparent capacitive touch panel with electromagnetic shielding effect as claimed in claim 1, wherein the conductive thin film is selected from a film of Indium Tin Oxide (ITO), Indium Zinc Oxide (IZO), Aluminum Zinc Oxide (AZO) or PEDOT (Poly(3,4-ethylenedioxythiophene)),

9. The transparent capacitive touch panel with electromagnetic shielding effect as claimed in claim 1, wherein the conductive thin film is a transparent conductive film installed on the upper protection layer by surface hardening process.

10. An electromagnetic shielding structure with a transparent touch panel, comprising
a liquid crystal display;
a transparent touch panel adhering to the liquid crystal display by gluing a conductive optical clear adhesive layer between the transparent touch panel and the liquid crystal display;
wherein a lateral side of the conductive optical clear adhesive layer is grounded through a conductor and can shield all the liquid crystal display; the conductive optical clear adhesive layer contains PEDOT/PSS copolymer [Poly (3,4-ethylenedioxythiophene)—poly (styrenesulfonate)] or antistatic agent material with a surface resistivity between 10 to 10,000 Ω·cm⁻².
